(19) United States
(12) Patent Application Publication
(10) Pub. No.: US 2023/0313035 A1
(43) Pub. Date: Oct. 5, 2023

(54) FLUORIDE PHOSPHOR, COMPLEX, AND LIGHT-EMITTING DEVICE

(71) Applicant: DENKA COMPANY LIMITED, Tokyo (JP)

(72) Inventors: Masayoshi ICHIKAWA, Tokyo (JP); Shunsuke MITANI, Tokyo (JP)

(73) Assignee: DENKA COMPANY LIMITED, Tokyo (JP)

(21) Appl. No.: 18/022,701

(22) PCT Filed: Aug. 16, 2021
(86) PCT No.: PCT/JP2021/029864

§ 371 Date: Feb. 22, 2023

(30) Foreign Application Priority Data
Aug. 25, 2020 (JP) 2020-141416

(51) Int. Cl. C09K 11/61; H01L 33/50

(52) U.S. Cl. CPC C09K 11/616; H01L 33/502

(57) ABSTRACT

A fluoride phosphor, a composition of which is represented by General Formula (1), in which in a case where a cumulative 50% value is denoted by D₅₀ and a cumulative 90% value is denoted by D₉₀ in a volume-based particle size distribution curve obtained by a laser diffraction scattering method, D₅₀ is 0.1 to 9.5 μm and D₉₀ is 0.5 to 16 μm. General Formula (1): A₂M_{(1-f)}F₆:Mn⁴⁺ₙ In General Formula (1), an element A is one or more alkali metal elements including K, an element M is a Si simple substance, a Ge simple substance, or a combination of Si and one or more elements selected from the group consisting of Ge, Sn, Ti, Zr, and Hf, and 0<n≤0.1 is satisfied.

### TECHNICAL FIELD

The present invention relates to a fluoride phosphor, a complex, and a light-emitting device.

### BACKGROUND ART

A fluoride phosphor represented by K₂SiF₆:Mn⁴⁺ (often abbreviated as a “KSF phosphor” or the like) is known as a phosphor that is capable of converting blue light emitted from a blue light-emitting diode into red light. This phosphor is efficiently excited by blue light.

In addition, the half width of the emission spectrum of this phosphor is narrow and sharp. Accordingly, in a case of using this phosphor as the red phosphor, it is possible to achieve excellent color rendering and excellent color reproducibility without decreasing the brightness of the white LED.

As a prior art of fluoride phosphors, for example, Patent Document 1 can be cited. Patent Document 1 describes a fluoride phosphor, a composition of which is represented by General Formula A₂M₍₁₋ₙ₎Fe₆:Mn⁴⁺ₙ, in which a bulk density is 0.80 g/cm³ or more and a mass median diameter is 30 μm or less. In the general formula, 0<n≤0.1 is satisfied, and an element A is one or more alkali metal elements including K, an element M is a Si simple substance, a Ge simple substance, or a combination of Si and one or more elements selected from the group consisting of Ge, Sn, Ti, Zr, and Hf.

### RELATED DOCUMENT

### Patent Document

[Patent Document 1] Japanese Unexamined Patent Publication No. 2019-001897

### SUMMARY OF THE INVENTION

### Technical Problem

Regarding the fluoride phosphor such as a KSF phosphor, applications to various use applications such as a use application to a display in addition to a use application to lighting have been studied based on the excellent light emission characteristics of the fluoride phosphor.

In the use application to lighting in the related art, generally according to the “potting method”, a fluorescent agent obtained by mixing a powdery fluoride phosphor and a resin is dropwise added and solidified onto a substrate using a dispenser to provide a complex that can convert blue light into light of another color.

On the other hand, in a case of considering applications of fluoride phosphors to new use applications, for example, applications to a miniaturized LED in recent years and a use application to a display (a mini LED display or the like), it is preferable that a relatively thin phosphor film can be formed by a coating method, a printing method, or another method instead of the potting method.

However, the preliminary study by the inventors of the present invention revealed that in a case where an attempt is made to form a phosphor layer according to a coating method, a printing method, or another method by using a fluoride phosphor in the related art, it may not be possible to form a sufficiently smooth and uniform phosphor film. In recent years, in particular, with the miniaturization and complication of devices, there has been a demand for providing a thin phosphor film; however, a fluoride phosphor in the related art has not satisfactorily met this demand.

The present invention has been made in consideration of such circumstances. One of the objects of the present invention is to provide a fluoride phosphor that is preferably applicable to the formation of a smooth and uniform phosphor film.

### Solution to Problem

The inventors of the present invention have completed the present invention provided below and solved the problem described above.

In a fluoride phosphor according to the present invention,
a composition thereof is represented by General Formula (1),
in which in a case where a cumulative 50% value is denoted by D₅₀ and a cumulative 90% value is denoted by D₉₀ in a volume-based particle size distribution curve obtained by a laser diffraction scattering method, D₅₀ is 0.1 to 9.5 μm and D₉₀ is 0.5 to 16 μm.

A₂M₍₁₋ₙ₎F₆:Mn⁴⁺ₙ General Formula (1):

In General Formula (1),
an element A is one or more alkali metal elements including K,
an element M is a Si simple substance, a Ge simple substance, or a combination of Si and one or more elements selected from the group consisting of Ge, Sn, Ti, Zr, and Hf, and
0<n≤0.1 is satisfied.

A complex according to the present invention contains the above-described fluoride phosphor and a sealing material that seals the fluoride phosphor.

A light-emitting device according to the present invention includes a light-emitting element that emits excitation light and the above-described complex that converts a wavelength of the excitation light.

### Advantageous Effects of Invention

According to the present invention, a fluoride phosphor that is preferably applicable to the formation of a smooth and uniform phosphor film is provided.

### BRIEF DESCRIPTION OF THE DRAWINGS

FIG. 1 is a view for describing an example of a complex/light-emitting device.

FIG. 2 is a view for describing another example of a complex/light-emitting device.

### DESCRIPTION OF EMBODIMENTS

Hereinafter, an embodiment according to the present invention will be described in detail while referring to drawings.

The drawings are for explanation purposes only. A shape or a dimensional ratio of each member in the drawing does not necessarily correspond to an actual article.

In the present specification, the description “X to Y” in the description of a numerical range represents X or more and Y or less unless specified otherwise. For example, “1% to 5% by mass” means “1% by mass or more and 5% by mass or less”.

<Fluoride Phosphor>

A composition of a fluoride phosphor according to the present embodiment is represented by General Formula (1) below.

A₂M₍₁₋ₙ₎F₆:Mn⁴⁺ₙ General Formula (1):

In General Formula (1),
an element A is one or more alkali metal elements including K,
an element M is a Si simple substance, a Ge simple substance, or a combination of Si and one or more elements selected from the group consisting of Ge, Sn, Ti, Zr, and Hf, and
0<n≤0.1 is satisfied.

In addition, in the fluoride phosphor according to the present embodiment, in a case where a cumulative 50% value is denoted by D₅₀ and a cumulative 90% value is denoted by D_{5G} in a volume-based particle size distribution curve obtained by a laser diffraction scattering method, D₅₀ is 0.1 to 9 μm and D₉₀ is 0.5 to 16 μm.

The fluoride phosphor according to the present embodiment has a composition represented by General Formula (1) and thus converts blue light emitted from a blue LED into red light.

Further, since D₅₀ is 0.1 to 9.5 μm and D₉₀ is 0.5 to 16 μm, the fluoride phosphor according to the present embodiment is preferably applied to the formation of a smooth and uniform phosphor film. The fact that D₅₀ is 9 μm or less and D₉₀ is 16 μm or less means that the fluoride phosphor according to the present embodiment contains few relatively large particles that may hinder the formation of a smooth and uniform phosphor film. That is, in a case where D₅₀ is 9 μm or less and D₉₀ is 16 μm or less, it is possible to form a smooth and uniform phosphor film.

Further, a phosphor film produced using the fluoride phosphor according to the present embodiment can have good optical characteristics. Specifically, a phosphor film produced using the fluoride phosphor according to the present embodiment tends to be less likely to transmit blue light, which is the excitation light (because in a case where the particle size of the phosphor is small, the dispersibility in the phosphor film is improved, and blue light is less likely to be transmitted). Such optical characteristics mean that, for example, the fluoride phosphor according to the present embodiment can be preferably applied to a micro-LED, a mini-LED, a wavelength conversion element of a projector, and the like, which will be described later.

By the way, in a case where D₅₀ is 0.1 μm or more or D₉₀ is 0.5 μm or more (that is, the particles that constitute the fluoride phosphor are “large to some extent”), an excessive decrease in the quantum efficiency of the fluoride phosphor is easily suppressed. In other words, the fluoride phosphor according to the present embodiment is preferably applicable to the formation of a smooth and uniform phosphor film, while having a good quantum efficiency.

The fluoride phosphor according to the present embodiment can be produced by using proper raw materials and adopting a proper production method and production conditions of such a production method. Although the details will be described later, for example, in a case a fluoride phosphor is precipitated by controlling the saturation degree of an aqueous solution, the progress of the crystal growth to a level more than necessary is suppressed by a production method in which water is added to the system at once in a short time to instantaneously increase the saturation degree. By such a production method, it is possible to produce a fluoride phosphor having a D₅₀ of 0.1 to 9.5 μm and a D₉₀ of 0.5 to 16 μm.

It is noted that for reference, D₅₀ and/or D₉₀ of the fluoride phosphor tends to become large depending on a known production method that does not employ such a method or production conditions of the known production method.

The description of the fluoride phosphor according to the present embodiment will be continued.

(Composition: About General Formula (1))

An element A is one or more alkali metal elements including K. Specifically, it can be a potassium simple substance or a combination of potassium and one or more alkali metal elements selected from lithium (Li), sodium (Na), rubidium (Rb), and cesium (Cs). From the viewpoint of chemical stability, the content proportion of the potassium in the element A is preferably high (for example, the potassium accounts for 50% by mole or more in the element A), where the element A is more preferably a potassium simple substance.

An element M is a Si simple substance, a Ge simple substance, or a combination of Si and one or more elements selected from the group consisting of Ge, Sn, Ti, Zr, and Hf. From the viewpoint of chemical stability, the content proportion of the silicon in the element M is preferably high (for example, the silicon accounts for 50% by mole or more in the element M), where the element M is more preferably a silicon simple substance.

In General Formula (1), it suffices that n satisfies 0<n≤0.1. However, from the viewpoint of better light emission characteristics, n preferably satisfies 0.01≤n≤0.04.

(D₅₀)

It suffices that D₅₀ of the fluoride phosphor according to the present embodiment is 0.1 to 9.5 μm; however, D₅₀ is preferably 1 to 9.5 μm, more preferably 3 to 9.2 μm, still more preferably 5 to 9 μm, and particularly preferably 7 to 9 μm. In a case where D₅₀, is moderately large, it is possible to form a smooth and uniform phosphor film having a sufficient quantum efficiency.

(D₉₀)

It suffices that D₉₀ of the fluoride phosphor according to the present embodiment is 0.5 to 16 μm; however, D₉₀ is preferably 3 to 16 μm, more preferably 5 to 16 μm, still more preferably 7 to 15 μm, particularly preferably 10 to 14 μm, and especially preferably 11 to 13 μm.

A moderately large D₉₀ makes it possible to form a smooth and uniform phosphor film having a sufficient quantum efficiency. In addition, the smoothness and uniformity of the phosphor film can be further increased by having a moderately small D₉₀. Further, in a case where D₉₀ is moderately small, it is easy to obtain a smooth and uniform phosphor film even in a case of forming a thin phosphor film.

(D₉₇ and D₁₀₀)

D₉₇ (a cumulative 97% value in the volume-based particle size distribution curve obtained by the laser diffraction scattering method) of the fluoride phosphor according to the present embodiment is preferably 20 μm or less, more preferably 18 μm or less, and still more preferably 17 μm or less. The lower limit of D₉₇ is, for example, 10 μm, and it is specifically 12 μm and more specifically 14 μm.

In addition, D₁₀₀ (a cumulative 97% value in the volume-based particle size distribution curve obtained by the laser diffraction scattering method) of the fluoride phosphor according to the present embodiment is preferably 40 μm or less, more preferably 35 μm or less, and still more preferably 30 μm or less. The lower limit of D₁₀₀ is, for example, 15 μm, and it is specifically 18 μm and more specifically 20 μm.

In a case where D₉, and D₁₀₀ are not too large, the smoothness and uniformity of the phosphor film can be further increased. Further, it is easy to obtain a smooth and uniform phosphor film even in a case of forming a thin phosphor film.

(D₁₀)

D₁₀ (a cumulative 10% value in the volume-based particle size distribution curve obtained by the laser diffraction scattering method) of the fluoride phosphor according to the present embodiment is preferably 5.5 μm or more and more preferably 6 μm or more. Although the upper limit of D₁₀ is not particularly limited, it is, for example, 10 μm or less and specifically 8 μm or less.

The fact that D₁₀ is a value that is large to some extent means that the proportion of microparticles having a low light emission efficiency is small. As a result, there is a tendency that the quantum efficiency is further increased in a case where D₁₀ is a value that is large to some extent.

By the way, a fluoride phosphor having a D₁₀ of 5.5 μm or more, a D₅₀ of 0.1 to 9.5 μm, and a D₉₀ of 0.5 to 16 μm is more preferably produced by a method of precipitating a fluoride phosphor from an aqueous solution, which will be described later. In a case where an attempt is made to reduce D₅₀ or D₉₀ by mechanically pulverizing a fluoride phosphor having a large particle size, a large amount of fine powder is generated, which resultantly tends to reduce D₁₀. The fluoride phosphor containing a large amount of fine powder due to pulverization tends to have a low light emission efficiency.

(γ: (D₉₀−D₅₀)/D₅₀)

In the fluoride phosphor according to the present embodiment, the value of γ defined by (D₉₀−D₅₀)/D₅₀ is preferably 0.5 or less and more preferably 0.46 or less. Although the lower limit thereof is not particularly limited, it is, for example, 0.25 or more and specifically 0.35 or more.

γ is an index that can be interpreted as a relative D₉₀ value in a case where D₅₀ is set as the base, and the smoothness and uniformity of the phosphor film can be further increased in a case a properly adjusting the value of γ in addition to setting the values of D₅₀ and D₉₀ themselves within the above-described ranges, respectively.

(δ: (D₉₀−D₁₀)/D₅₀)

In the fluoride phosphor according to the present embodiment, the value of 5 defined by (D₉₀−D₁₀)/D₅₀ is preferably 0.75 or less and more preferably 0.73 or less. Although the lower limit thereof is not particularly limited, it is, for example, 0.30 or more and specifically 0.50 or more.

δ can be regarded as an index that indicates the “width” of the particle size distribution. The fact that the width of the particle size distribution of the fluoride phosphor is narrow means that the particle sizes of the particles that constitute the fluoride phosphor are relatively “uniform”. Accordingly, in a case of setting 6 to 0.75 or less, the smoothness and uniformity of the phosphor film can be further increased.

As described above, in order to increase D₁₀, it is preferable to employ a method of precipitating a fluoride phosphor from an aqueous solution without carrying out mechanical pulverization (details thereof will be described later) as a production method for a fluoride phosphor. δ decreases as D₁₀ increases, and thus from the viewpoint of making δ 0.75 or less as well, it is preferable to employ a method of precipitating a fluoride phosphor from an aqueous solution as the production method.

(Quantum Efficiency)

The internal quantum efficiency of the fluoride phosphor according to the present embodiment is preferably 70% or more and more preferably 75% or more. Although the upper limit of the internal quantum efficiency is not particularly limited, the upper limit thereof is, for example, practically 95% and specifically 90%.

The external quantum efficiency of the fluoride phosphor according to the present embodiment is preferably 45% or more, more preferably 46.5% or more, and still more preferably 48% or more. Although the upper limit of the external quantum efficiency is not particularly limited, it is, for example, practically 70%, specifically 65%, and more specifically 61%.

As a general trend, although a quantum efficiency of a fluoride phosphor having a small particle size tends to be low, the fluoride phosphor according to the present embodiment exhibits a relatively good quantum efficiency. In particular, in a case of respectively setting D₁₀ and & within the numerical ranges described above, it is easy to obtain a smooth and uniform phosphor film while maintaining a good quantum efficiency.

<About Production Method>

The production method for the fluoride phosphor according to the present embodiment is not limited. The fluoride phosphor according to the present embodiment can be produced by using a proper material and selecting a proper production method and proper production conditions. Although examples of the specific production method will be described in Examples below, two patterns of production methods will be described as a “production method 1” and a “production method 2” below.

(Production Method 1)

A production method 1 mainly includes a dissolution step and a precipitation step. Hereinafter, these steps will be described. These steps can be carried out at room temperature.

Dissolution Step

In the dissolution step, in general, (i) a raw material that supplies the element A (K or the like), (ii) a raw material that supplies the element M (preferably Si), (iii) a raw material that supplies F, and the like are is dissolved hydrofluoric acid. One raw material may serve as two or more of (i) to (iii). For example, K₂SiF₆, which will be described later, serves as all of the raw materials (i) to (iii).

The concentration of hydrogen fluoride in the hydrofluoric acid before dissolving the raw materials (i) to (iii) is preferably 50% to 60% by mass.

The raw material that supplies the element A is preferably a compound of the element A from the viewpoint of chemical stability. For example, an oxide, hydroxide, fluoride, or carbonate of the element A can be used.

The raw material that supplies F can be a fluoride as a raw material for another element (A, M, or Mn). In addition, fluorine is also supplied from hydrogen fluoride in the hydrofluoric acid that is used as a solvent.

A particularly preferred raw material (other than hydrofluoric acid in the hydrofluoric acid) that is used in the dissolution step is K₂SiF₆.

Precipitation Step

In the precipitation step, a raw material for supplying Mn and a suitable amount of water are added to a system as quickly as possible. As a result, the system rapidly becomes to be in a supersaturated state, and a fluoride phosphor having a composition represented by General Formula (1) is precipitated. Here, “as quickly as possible” depends on the scale of the system. However, it refers to that in a case of water, preferably about 1.5 L of water is added to the system in about 3 seconds, for example, in a case where 1 L of hydrofluoric acid has been used in the dissolution step. In addition, regarding the raw material for supplying Mn, it means that preferably entire required amount is added to the system at once.

It is conceived that such an operation (an operation that rapidly brings the system into a supersaturated state) suppresses the progress of the crystal growth to a level more than necessary, whereby it is possible to obtain a fluoride phosphor having a D₅₀ of 0.1 to 9.5 μm and a D₅₀ of 0.5 to 16 μm.

Examples of the raw material for supplying Mn in the precipitation step include a hexafluoromanganate, a permanganate, an oxide (excluding a permanganate), a fluoride (excluding a hexafluoromanganate), a chloride, a sulfate, and a nitrate. Among them, a fluoride is preferable since Mn can be efficiently substituted for the Si site in the fluoride phosphor and good light emission characteristics can be obtained, and among fluorides, a hexafluoromanganate is preferable. Examples of the hexafluoromanganate include Na₂MnFE₆, K₂MnF_{F}, Rb₂MnF₆, MgMnF₆, CaMnF₆, SrMnF₆, and BaMnF₆. In particular, K₂MnF₆ is preferable since it can simultaneously supply F or K (corresponding to the element A), which constitutes the fluoride phosphor in addition to Mn.

The fluoride phosphor obtained in the precipitation step is recovered by solid-liquid separation by filtration or the like and washed with an organic solvent such as methanol, ethanol, or acetone. In a case where the fluoride phosphor is washed with water, a part thereof may be hydrolyzed to generate a brown manganese compound, which deteriorates the properties of the fluoride phosphor. As a result, it is preferable to use an organic solvent in the washing step. Further, in a case of carrying out washing several times with a hydrofluoric acid reaction solution before carrying out washing with an organic solvent, it is possible to dissolve and remove impurities generated in trace amounts. The concentration of the hydrofluoric acid in the hydrofluoric acid reaction solution that is used for washing is preferably 5% by mass or more from the viewpoint of suppressing the decomposition of the fluoride phosphor, and it is more preferably 60% by mass or less from the viewpoint of the solubility of the fluoride phosphor. After the washing step, it is preferable to dry the fluoride phosphor to sufficiently evaporate the washing liquid.

Alternatively, a sieve having a predetermined mesh size may be used for classification, or coarse particles may be removed.

(Production Method 2)

Although a production method 2 is different from the production method 1, it is similar thereto in that the fluoride phosphor having the composition represented by General Formula (1) is precipitated by rapidly bringing the system into a supersaturated state. The production method 2 mainly includes a dissolution step, a step of adding a raw material that supplies Mn, and a precipitation step.

Hereinafter, these steps will be described. These steps can be carried out at room temperature.

Dissolution Step

The dissolution step in the production method 2 can be the same as that in the production method 1.

Step of Adding Raw Material that Supplies Mn

In the step of adding a raw material that supplies Mn, the “raw material for supplying Mn” described in the precipitation step of the production method 1, such as K₂MnFE₆, is added to the solution obtained in the dissolution step, stirred, and dissolved.

Precipitation Step

In the precipitation step in the production method 2, for example, an aqueous solution in which about 10 to 40 g/L of potassium hydrogen fluoride (KHF₂) has been dissolved is added to the system as quickly as possible. As a result, the system is rapidly brought into a supersaturated state, and a fluoride phosphor having a composition represented by General Formula (1) is precipitated. Here, “as quickly as possible” depends on the scale of the system. However, it means that, preferably, about 1.5 L of the above-described aqueous solution is added to the system in about 3 seconds, for example, in a case where 1 L of an aqueous solution of hydrofluoric acid has been used in the dissolution step. It is conceived that rapidly bringing the system into a supersaturated state in this way suppresses the progress of the crystal growth to a level more than necessary, whereby it is possible to obtain a fluoride phosphor having a D₅₀ of 0.1 to 9.5 μm and a D₉₀ of 0.5 to 16 μm.

A potassium source such as KF may be used instead of KHF₂ in the precipitation step.

In the production method 2 as well, as in the production method 1, it is preferable to carry out filtration, washing, classification by sieving or removal of coarse particles, and the like.

<Complex and Light-Emitting Device>

The complex according to the present embodiment includes the above-described fluoride phosphor and a sealing material that seals the fluoride phosphor.

In addition, the light-emitting device according to the present embodiment includes a light-emitting element that emits excitation light and the above-described complex that converts a wavelength of the excitation light.

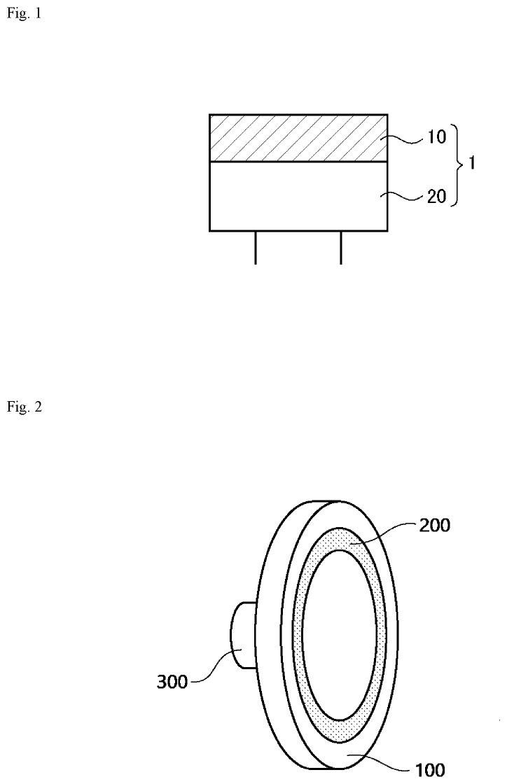

An example of each of a complex and a light-emitting device will be described below with reference to FIG. 1. A complex and a light-emitting device different from those in FIG. 1 will be described with reference to FIG. 2.

(FIG. 1)

FIG. 1 is a schematic diagram of a light-emitting device 1.

The light-emitting device 1 includes a complex 10 and a light-emitting element 20. The complex 10 is provided in contact with the upper part of the light-emitting element 20.

The light-emitting element 20 is typically a blue LED. Terminals are present in the lower part of the light-emitting element 20. The light-emitting element 20 can emit light by being connected to terminals to a power supply.

The excitation light emitted from the light-emitting element 20 is subjected to wavelength conversion by the complex 10. In a case where the excitation light is blue light, the blue light is subjected to wavelength conversion into red light by the complex 10 containing the fluoride phosphor.

The complex 10 can be composed of the above-described fluoride phosphor and a sealing material that seals the fluoride phosphor.

As the sealing material, it is possible to use, for example, various curable resin materials (materials that are cured by heat and/or light). Any curable resin material can be used as long as it is sufficiently transparent and provides the optical characteristics required for displays and lighting devices.

Examples of the sealing material include a silicone resin material. The silicone resin material is preferably a silicone resin material supplied by DuPont Toray Specialty Materials K.K. or Shin-Etsu Chemical Co., Ltd. from the viewpoint of excellent heat resistance in addition to high transparency. In addition, examples of the sealing material also include an epoxy resin material and a urethane resin material.

The amount of fluoride phosphor particles in the complex 10 is, for example, 10% to 70% by mass and preferably 25% to 55% by mass.

The size and shape of the light-emitting element 20 are not particularly limited. Depending on the use application of the light-emitting device 1, the light-emitting element 20 can have any size and shape.

The light-emitting device 1 can be, for example, a micro-LED or mini-LED for manufacturing a self-luminous display. The micro-LED generally refers to an LED in which chips constituting pixels of a self-luminous display have a size of less than 100 μm square. In addition, the mini-LED refers to an LED in which chips constituting pixels of a self-luminous display have a size of 100 μm or more (more specifically, 100 μm or more and 200 μm or less). In a case of using a plurality of micro-LEDs or mini-LEDs are used, a self-luminous display can be manufactured.

Specifically, by using the light-emitting device 1 as a pixel (typically a red pixel) and using a combination of a micro-LED or mini-LED that emits blue light and a micro-LED or mini-LED that emits green light, a self-luminous display that enables the color display can be constituted.

Regarding the micro LED displays and the mini LED displays, the following documents can be referenced; “2019 Latest trend survey of next-generation display technology and related materials/processes (Fuji Chimera Research Institute, Inc.)”, “Appl. Sci. 2018, 8, 1557”, “The journal of the Institute of Image Information and Television Engineers Vol. 73, No. 5, pp. 939-942 (2019)”, and the like.

In the present embodiment, since a fluoride phosphor having a D₅₀ of 0.1 to 9.5 μm and a D₉₀ of 0.5 to 16 μm is used, it is easy to increase the smoothness and uniformity of the complex 10 or it is easy to make the complex 10 thin.

In a case of providing the smooth and uniform complex 10, it is possible to obtain, for example, effects such as the improvement in the yield of the light-emitting device 1 and the suppression of variations in the light emission characteristics of the light-emitting device 1. The effect of “the suppression of variations” is an effect desirable particularly in a case where the light-emitting device 1 is applied to a self-luminous display. In the self-luminous display in which variations in the light emission characteristics of the light-emitting device 1 are suppressed, it is possible to “make uniform” the light emission characteristics between pixels.

In addition, being able to make the complex 10 thin also contributes to the miniaturization of the light-emitting device 1 as a whole. That is, in a case of making the complex 10 thin, it is easy to manufacture a “small light-emitting device 1” such as a micro-LED or a mini-LED.

By the way, the light emitted from the fluoride phosphor according to the present embodiment tends to have a relatively large x value in the chromaticity diagram. For this reason as well, it is preferable to constitute a self-luminous display using the fluoride phosphor according to the present embodiment.

(FIG. 2)

FIG. 2 is a view schematically illustrating a wavelength conversion member of a projector, which is an example of the complex according to the present embodiment. This wavelength conversion member is a so-called transmissive rotating fluorescent plate (a phosphor wheel).

In this wavelength conversion member, a phosphor layer 200 (a complex) is formed along a rotation direction of a disc-shaped substrate 1 that is rotationally driven by a motor 300. The region where the phosphor layer 2 is formed includes a blue light incident region where blue light (typically blue laser light) from a blue light source is incident.

As the substrate 100 is rotationally driven around a rotation axis by the motor 300, the blue light incident region moves relative to the substrate 100 around the rotation axis.

The phosphor layer 200 is a complex including the phosphor particles and a sealing material that seals the phosphor particles.

Examples of the sealing material for forming the phosphor layer 200 (the complex) include the same ones as those described in the light-emitting device of FIG. 1. The amount of the phosphor particles in the phosphor layer 200 (the complex) is, for example, 10% to 70% by mass, and preferably 25% to 55% by mass.

The substrate 100 is preferably configured with a material that transmits visible light. Examples of the material of the substrate 100 include quartz glass, crystal, sapphire, optical glass, and a transparent resin. A dielectric multi-layer film (not illustrated in the drawing) may be provided between the substrate 100 and the phosphor layer 200. The dielectric multi-layer film functions as a dichroic mirror, transmits blue light having a wavelength of approximately 450 nm, and reflects light having a wavelength of 490 nm or more including a wavelength range (490 nm to 750 nm) of the phosphor emitted from the phosphor layer 200.

The shape of the substrate 100 is typically disc shape; however, the shape thereof is not limited to the disc-shape.

The phosphor layer 200 rotates together with the substrate 1 during use. In such a substrate 100, in a case where the blue light (laser light) is incident on the phosphor layer 200, a part of the phosphor layer 200 corresponding to the blue light incident region generates heat. As the substrate 100 rotates, this heated part (the heated part) moves in a circle around the rotation axis and returns to the blue light incident region, and this cycle is repeated. As described above, the irradiation position of the blue light with respect to the phosphor layer 200 is sequentially changed to suppress excessive heat generation.

At least a part of the blue light incident on the wavelength conversion member is subjected to wavelength conversion into red light by the phosphor layer 200. At least a part of the red light is emitted to a side opposite to the side to which the blue light is incident.

Since the above-described fluoride phosphor and sealing material are used, the smooth and uniform phosphor layer 200 (the complex) can be provided. This contributes to, for example, the improvement in the yield of the wavelength conversion member.

A projector (a light-emitting device) using a blue light source typically includes a blue light source such as a blue laser, a wavelength conversion member that converts a wavelength of blue light emitted from the blue light source, a modulation element that modulates light emitted from the wavelength conversion element by an image signal, and projection optical system that projects the light modulated by the modulation element.

For specific configurations of the wavelength conversion element and the projector, FIG. 1 of Japanese Unexamined Patent Publication No. 2013-162021 and the description thereof, the description of Japanese Unexamined Patent Publication No. 2013-92796, and the like can be referred to. In addition, a well-known technology can be appropriately applied to the configuration of the wavelength conversion element and the projector.

The embodiments according to the present invention have been described above; however, these are examples according to the present invention, and thus it is possible to adopt various configurations other than the above. In addition, the present invention is not limited to the embodiments described above and modifications, improvements, and the like are included in the present invention in a range in which it is possible to achieve the purpose of the present invention.

### EXAMPLES

The aspects according to the present invention will be described in more detail based on Examples and Comparative Examples. It is should be noted that the present invention is not limited to only Examples.

In the following description, the following raw materials were used.

Hydrofluoric acid: manufactured by Stellachemifa Corporation
K₂SiF₆: solid, manufactured by MORITA CHEMICAL INDUSTRIES CO., LTD.
K₂MnF₆: prepared by the method described in paragraph 0042 of Japanese Unexamined Patent Publication No. 2019-1897
KHF₂: FUJIFILM Wako Pure Chemical Corporation, special grade reagent
SiO₂: manufactured by Kojundo Chemical Laboratory. Co., Ltd.

### Example 1

At room temperature, 1,000 mL of an aqueous solution of hydrofluoric acid having a concentration of 55% by mass was supplied to a Teflon (registered trade name) beaker. To this, 50 g of K₂SiF₆ was added and stirred for 5 minutes to obtain a homogeneous solution.

While continuing the stirring, 6 g of K₂MnF_{E} and 1,500 mL of ion-exchanged water were added at the same time to this homogeneous solution. At this time, the entire amount of K₂MnF₆ was added at once, and the entire amount of ion-exchanged water was added in 3 seconds (that is, added at a rate of 500 mL/s). This started the precipitation of a yellow solid content. Then, stirring was continued for 5 minutes.

After stirring was completed, the solution was allowed to stand to precipitate a yellow solid content. After confirming the precipitation, the supernatant solution was removed, and the yellow solid content was washed with hydrofluoric acid of a concentration of about 24% by mass and then washed using methanol. The washed solid content was filtered to separate and recover the solid content, followed by a drying treatment to evaporate and remove residual methanol. After the drying treatment, using a nylon sieve having a mesh size of 75 μm, only the yellow powder that passed through this sieve was classified and recovered.

As described above, a fluoride phosphor was obtained.

### Example 2

A fluoride phosphor was obtained in the same manner as in Example 1, except that the stirring time after adding K₂SiF₆ to the aqueous solution of hydrofluoric acid was changed from 5 minutes to 10 minutes.

### Example 3

At room temperature, 1,000 mL of hydrofluoric acid having a concentration of 55% by mass was supplied to a Teflon (registered trade name) beaker. To this, 50 g of K₂SiF₆ was added and stirred for 10 minutes to obtain a homogeneous solution.

While continuing the stirring, 6 g of K₂MnF was added to this homogeneous solution, and stirring was further carried out for 30 seconds. Then, an aqueous solution of KHF₂ prepared in another beaker (an aqueous solution obtained by adding 35 g of KHF₂ to 1,500 mL of ion-exchanged water and stirring for 5 minutes to uniformly dissolve the resultant mixture) was added thereto. The entire amount of this aqueous solution was added thereto in 3 seconds (that is, it was added at a rate of 500 mL/s). This started the precipitation of a yellow solid content. Then, stirring was continued for 5 minutes.

The operations such as recovery, washing, and the like of the solid content after stirring were the same as those in Example 1. As a result, a fluoride phosphor was obtained.

### Example 4

A fluoride phosphor was obtained in the same manner as in Example 3, except that an aqueous solution obtained by adding 27 g of KHF₂ to 1,500 mL of ion-exchanged water and stirring for 5 minutes to uniformly dissolve the resultant mixture was used as the KHF₂ aqueous solution.

### Comparative Example 1

Comparative Example 1 is a production example corresponding to the production of a fluoride phosphor by a poor solvent method in the related art.

At room temperature, 1,000 mL of an aqueous solution of hydrofluoric acid having a concentration of 55% by mass was supplied to a Teflon (registered trade name) beaker. To this, 50 g of K₂SiF₆ and 3 g of K₂MnF were added and stirred for 10 minutes to obtain a homogeneous solution.

1,500 mL of ion-exchanged water was added to this solution over 10 seconds (that is, it was added at a rate of 150 mL/s). This started the precipitation of a yellow solid content. Then, stirring was continued for 5 minutes.

The operations such as recovery, washing, and the like of the solid content after stirring were the same as those in Example 1. As a result, a fluoride phosphor was obtained.

### Comparative Example 2

Comparative Example 2 is a production example of a fluoride phosphor by a production method called a silica addition method in the related art.

At room temperature, 700 mL of hydrofluoric acid having a concentration of 55% by mass was supplied to a Teflon (registered trade name) beaker. To this, 93.8 g of KHF₂ was added, and stirring was carried out for 15 minutes. Then, 4.0 g of K₂MnF was added, and stirring was carried out for 30 seconds. Then, 24 g of SiO₂ was added, and stirring was carried out for 10 minutes.

The operations such as recovery, washing, and the like of the solid content after stirring were the same as those in Example 1. As a result, a fluoride phosphor was obtained.

### Comparative Example 3

Comparative Example 3 is also a production example of a fluoride phosphor by a production method called a silica addition method in the related art.

A fluoride phosphor was obtained in the same manner as in Comparative Example 2, except that the stirring time after adding 4.0 g of K₂MnF was changed from 30 seconds to 45 seconds.

<Identification: Crystal Phase Measurement and Like>

An X-ray diffractometer was used to obtain an X-ray diffraction pattern of each of the fluoride phosphors (the yellow powders) obtained in Examples 1 to 4. The obtained X-ray diffraction pattern was the same as the X-ray diffraction pattern of the K₂SiF₆ crystal. From this, it was confirmed that K₂Si₍₁₋ₙ₎F_{F}:Mn⁴⁺ₙ is obtained in a single phase.

Apart from the X-ray diffraction, the fluoride phosphor (the yellow powder) obtained in Example 1 was dissolved using each of sodium carbonate and boric acid and analyzed by ICP emission spectrometry to determine the contents of K, Si, and Mn. In addition, 0.1 g of the fluoride phosphor (the yellow powder) was dissolved in water, and the content of F was analyzed according to the measurement method of “7.2 Purity” of JIS K 8821 “Sodium fluoride (reagent)”. Based on these analyses, the value of n in General Formula (1) was 0.03.

Based on the charging ratios of the raw materials and the like, the values of n are conceived to be approximately the same in Examples 2 to 4 as well.

<Particle Size Distribution Measurement by Laser Diffraction Scattering Method>

30 mL of ethanol was weighed into a 50 mL beaker, and 0.03 g of the fluoride phosphor was added thereto. Next, the container was set in a homogenizer (manufactured by NISSEI Corporation, product name: US-150E) of which the output had been adjusted to “Altitude: 100%” in advance, and pretreatment was carried out for 3 minutes.

From the solution prepared in this way, a volume-based particle size distribution curve was obtained by using a laser diffraction scattering-type particle size distribution analyzer (product name: MT3300EXII, manufactured by MicrotracBEL Corp.). Then, D₁₀, D₅₀, D₉₀, D₅₇, and D₁₀₀ were determined from the obtained curve, and further, γ=(D₉₀−D₅₀)/D₅₀ and δ=(D₉₀−D₁₀)/D₅₀ were determined.

<Evaluation of Light Emission Characteristics (Quantum Efficiency and Chromaticity)>

A standard reflector plate (manufactured by Labsphere, Inc., product name: Spectralon) having a reflectivity of 99% was set in an opening portion ((10 mm) on a side of an integrating sphere (ρ60 mm). Monochromatic light split at a wavelength of 455 nm from a light emitting source (Xe lamp) was introduced in the integrating sphere by an optical fiber, and a spectrum of the reflected light was measured by a spectrophotometer (product name: MCPD-7000 manufactured by Otsuka Electronics Co., Ltd.). At this time, the number of excitation light photons (Qex) was calculated from the spectrum in a wavelength range of 450 to 465 nm.

Next, a recessed cell which had been filled with the fluoride phosphor so that the surface was smooth was set in the opening portion of the integrating sphere and irradiated with monochromatic light having a wavelength of 455 nm to measure spectra of the excited reflected light and the fluorescence with a spectrophotometer. Based on the obtained spectral data, the number of excited reflected light photons (Qref) and the number of fluorescence photons (Qem) were calculated. The number of excited reflected light photons was calculated in the same wavelength range as that of the number of excitation light photons, and the number of fluorescence photons was calculated in a range of 465 to 800 nm. From the obtained three kinds of numbers of photon, the absorbance (=(Qex−Qref)/Qex×100), the internal quantum efficiency (=Qem/(Qex−Qref)×100) and the external quantum efficiency (=Qem/Qex×100) were determined.

In addition, based on the data obtained by this measurement, the x value and y value in the xy chromaticity diagram of the fluorescence emitted from the fluoride phosphor were determined using the analysis software attached to the apparatus.

<Smoothness, Uniformity, and Optical Characteristics of Phosphor Film>

First, a phenyl silicone resin (OE-6630, manufactured by Dow Corning Corp.) and the fluoride phosphor were mixed using a mixer ARE-310 (manufactured by THINKY CORPORATION) while carrying out defoaming. As a result, a mixture for forming a phosphor film was obtained. The amount of the fluoride phosphor used was such that the ratio of the fluoride phosphor in the mixture was 40% by mass.

Next, the above mixture was applied between two PFA (fluororesin) films having a thickness of 100 μm and allowed to pass through a roller by which the thickness was set to 50 μm. Then, a heat treatment was carried out at 150° C. for 1 hour. After cooling, the PFA film was peeled off, and cutting was carried out to a size of 20 mm×20 mm. As a result, a sheet-shaped phosphor film (a complex) was obtained.

The obtained phosphor film was visually observed. A case where ununiformity was not recognized by a visual observation and was smooth was evaluated as (◯), a case where ununiformity was clearly recognized by a visual observation was evaluated as (x), and a case where ununiformity which was not recognized at first glance but was recognized by a careful visual observation, was evaluated as poor (Δ).

In addition, the obtained phosphor film was set on a blue LED having an emission wavelength of 455 rim, and the blue LED was caused to emit light. Then, the brightness of the light emitted to a side opposite to the side on which the blue LED in the phosphor film is present was evaluated using a total luminous flux measurement system HM9100 (manufactured by Otsuka Electronics Co., Ltd.). Using Example 1 as the base, a case where the same level of brightness as Example 1 was obtained was evaluated as good (⊚), a case where it was brighter than Example 1 was evaluated as very good (◯), a case where it was slightly darker than Example 1 was evaluated as slightly bad (Δ), and a case where it was clearly darker than Example 1 was evaluated as bad (x).

Various measurement and evaluation results are summarized in the table below.

TABLE 1

| | | | | | | | | | Internal | External | | | | |
|---|---|---|---|---|---|---|---|---|---|---|---|---|---|---|
| | | | | | | (D₉₀ − | (D₉₀ − | | quantum | quantum | Chroma- | Chroma- | Smoothness | Optical |
| | | | | | | D₁₀)/ | D₅₀)/ | Absor- | effi- | effi- | ticity | ticity | and | Charac- |
| | D₁₀ | D₅₀ | D₉₀ | D₉₇ | D₁₀₀ | D₅₀ | D₅₀ | bance | ciency | ciency | x | y | uniformity | teristics |
| Example 1 | 6.1 | 8.3 | 12.0 | 15.1 | 26.0 | 0.71 | 0.45 | 62.6% | 78.3% | 49.0% | 0.694 | 0.306 | ◯ | ◯ |
| Example 2 | 6.4 | 8.6 | 12.4 | 15.6 | 26.0 | 0.70 | 0.44 | 63.1% | 79.3% | 50.0% | 0.694 | 0.306 | ◯ | ◯ |
| Example 3 | 6.2 | 8.5 | 12.5 | 15.8 | 26.0 | 0.73 | 0.46 | 69.5% | 87.6% | 60.8% | 0.694 | 0.305 | ◯ | ⊚ |
| Example 4 | 6.6 | 8.9 | 12.8 | 16.0 | 26.0 | 0.70 | 0.44 | 69.3% | 86.6% | 60.0% | 0.694 | 0.306 | ◯ | ⊚ |
| Comparative | 18.4 | 28.2 | 42.8 | Data | 87.6 | 0.87 | 0.52 | 67.0% | 81.4% | 54.5% | 0.694 | 0.306 | X | X |
| Example 1 | | | | not | | | | | | | | | | |
| | | | | avail- | | | | | | | | | | |
| | | | | able | | | | | | | | | | |
| Comparative | 5.2 | 9.0 | 20.6 | 31.9 | 61.9 | 1.71 | 1.29 | 51.8% | 71.9% | 37.2% | 0.694 | 0.306 | Δ | X |
| Example 2 | | | | | | | | | | | | | | |
| Comparative | 5.1 | 8.4 | 17.0 | 25.8 | 52.0 | 1.42 | 1.02 | 51.4% | 79.0% | 40.6% | 0.694 | 0.306 | Δ | Δ |
| Example 3 | | | | | | | | | | | | | | |

As shown in the table above, the phosphor films formed using the fluoride phosphors of Examples 1 to 4 (D₅₀ is 0.1 to 9.5 μm, and D₉₀ is 0.5 to 16 μm) are smooth and the ununiformity of the film is observed (Examples 1 to 4). On the other hand, in Comparative Examples 1 to 3, ununiformity is observed in the phosphor films formed using the fluoride phosphors having a D₅₀ of more than 9.5 μm or a D₉₀ of more than 16 μm.

In addition, the phosphor films formed using the fluoride phosphors of Examples 1 to 4 exhibit good optical characteristics (brightness).

Further, the quantum efficiencies of the fluoride phosphors of Examples 1 to 4 are comparable to those of Comparative Examples 1 to 3.

This application claims priority based on Japanese Patent Application No. 2020-141416 filed on Aug. 25, 2020, and all contents of the disclosure are incorporated herein.

### REFERENCE SIGNS LIST

1: light-emitting device
10: complex
20: light-emitting element
100: substrate
200: phosphor layer (complex)
300: motor

1. A fluoride phosphor, a composition of which is represented by General Formula (1),
wherein in a case where a cumulative 50% value is denoted by D₅₀ and a cumulative 90% value is denoted by D₉₀ in a volume-based particle size distribution curve obtained by a laser diffraction scattering method, D₅₀ is 0.1 to 9.5 μm, and D₉₀ is 0.5 to 16 μm,
A₂M₍₁₋ₙ₎F₆:Mn⁴⁺ₙ General Formula (1):
in General Formula (1),
an element A is one or more alkali metal elements including K,
an element M is a Si simple substance, a Ge simple substance, or a combination of Si and one or more elements selected from the group consisting of Ge, Sn, Ti, Zr, and Hf, and
0<n≤0.1 is satisfied.

2. The fluoride phosphor according to claim 1,
wherein a value of γ defined by γ=(D₉₀−D₅₀)/D₅₀ is 0.5 or less.

3. The fluoride phosphor according to claim 1,
wherein in a case where a cumulative 10% value in the volume-based particle size distribution curve obtained by the laser diffraction scattering method is denoted by D₁₀, a value of δ defined by δ=(D₅₀−D₁₀)/D₅₀ is 0.75 or less.

4. The fluoride phosphor according to claim 1,
wherein in a case where a cumulative 97% value in the volume-based particle size distribution curve obtained by the laser diffraction scattering method is denoted by D₉₇, D₉₇ is 20 μm or less.

5. The fluoride phosphor according to claim 1,
wherein in a case where a cumulative 10% value in the volume-based particle size distribution curve obtained by the laser diffraction scattering method is denoted by D₁₀, D₁₀ is 5.5 μm or more.

6. The fluoride phosphor according to claim 1,
wherein an external quantum efficiency in a case where the fluoride phosphor is excited by light having a wavelength of 455 nm is 45% or more.

7. A complex comprising:
the fluoride phosphor according to claim 1; and
a sealing material that seals the fluoride phosphor.

8. A light-emitting device comprising;
a light-emitting element that emits excitation light; and
the complex according to claim 7 that converts a wavelength of the excitation light.
